(19) United States
(12) Patent Application Publication
(10) Pub. No.: US 2018/0076399 A1
(43) Pub. Date: Mar. 15, 2018

(54) MULTI-FUNCTIONAL SUBSTRATE FOR OLED LIGHTING APPLICATION

(71) Applicant: SABIC Global Technologies B.V., Bergen op Zoom (NL)

(72) Inventor: Sang Hoon KIM, Seoul (KR)

(21) Appl. No.: 15/561,160

(22) PCT Filed: Mar. 24, 2016
(86) PCT No.: PCT/IB2016/051700

§ 371 Date: Sep. 25, 2017

Related U.S. Application Data
(60) Provisional application No. 62/140,774, filed on Mar. 31, 2015.

(51) Int. Cl. H01L 51/00; H01L 51/52; H01L 27/32; H01L 51/56

(52) U.S. Cl. CPC H01L 51/0097; H01L 51/5215; H01L 51/5268; H01L 51/5275; H01L 2251/301; H01L 51/56; H01L 2251/5338; H01L 2251/308; H01L 2251/305; H01L 27/322

(57) ABSTRACT

The disclosure concerns multifunctional flexible substrate suitable for use in an organic light emitting diode element, said flexible substrate comprising: a barrier layer; a transparent electrode layer; and a microlens array layer comprising particles; wherein the barrier layer, the electrode layer, and the microlens array layer are formed into a single sheet.

### RELATED APPLICATIONS

This application claims benefit to U.S. Patent Application No. 62/140,774 filed on Mar. 31, 2015, the disclosure of which is incorporated herein in its entirety.

### TECHNICAL FIELD

The disclosure concerns multifunctional flexible substrates useful in organic light emitting diodes.

### BACKGROUND

An emerging trend in electronics industry is the use of flexible, thinner, lighter and cost competitive articles. In organic light-emitting diode (OLED) lighting applications, glass substrates have been used for its high performance property in WVTR (water vapor transmission rate, g/m²/day). Glass, however, is fragile and lacking in flexibility. To realize design freedom in shape for luminaire, it is necessary to have substrate which is flexible, thinner, and lighter. A state of the art flexible OLED device is composed of a substrate, a barrier, an electrode (anode), an organic, a cathode, and an encapsulate layer.

FIG. 1 shows the schematic of a conventional OLED device. Generally, in case of flexible OLED lighting, the barrier film substrate itself is provided from a film company. And then an electrode material such as ITO (indium tin oxide) or PEDOT-PSS (poly(3,4-ethylenedioxythiophene)-poly(styrenesulfonate)) polymer electrode could be laminated or coated by vacuum process on the barrier film. FIG. 2 shows a conventional flexible barrier substrate. Each layer is made separately and subsequently combine, which means several process steps are involved that result in an increase to fabrication costs.

It is desirable to provide a product and process that reduces these costly process steps.

### SUMMARY

In some aspects, the disclosure concerns multifunctional flexible substrates suitable for use in an organic light emitting diode element, the flexible substrate comprising a barrier layer; a transparent electrode layer; and a microlens array layer comprising particles; wherein the barrier layer, the electrode layer, and the microlens array layer are formed into a single sheet in the absence of an adhesive layer.

Certain aspects concern a single layer multifunctional flexible substrate comprising a barrier layer; a transparent electrode layer; at least one microlens array layer comprising particles; at least one refractive index matching layer; and a phosphor layer. In some constructs, the barrier layer, the electrode layer, and the microlens array layer are formed into a single sheet in the absence of an adhesive layer. In some constructs, no adhesive is used in forming the multilayers into a single sheet.

The disclosure also concerns articles comprising such flexible substrates and methods of making such articles and substrates.

### BRIEF DESCRIPTION OF THE DRAWINGS

FIG. 1 shows the schematic of a conventional OLED device. Generally, in the case of a flexible OLED lighting, the barrier film substrate itself is provided from a film company. Then, an electrode material such as ITO (indium tin oxide) or PEDOT-PSS (Poly(3,4-ethylenedioxythiophene)-poly(styrenesulfonate)) polymer electrode is laminated or coated by vacuum process on the barrier substrate. Finally, the remaining layers are laminated together to form the OLED device.

FIG. 2 presents a schematic of conventional flexible barrier substrate.

FIG. 3 shows an integrated substrate with light extraction, barrier, and electrode functions.

FIG. 4 presents a schematic of a substrate having a micro lens array with particles and optionally a refractive index matching layer.

FIG. 5 presents examples of applicable substrate structures.

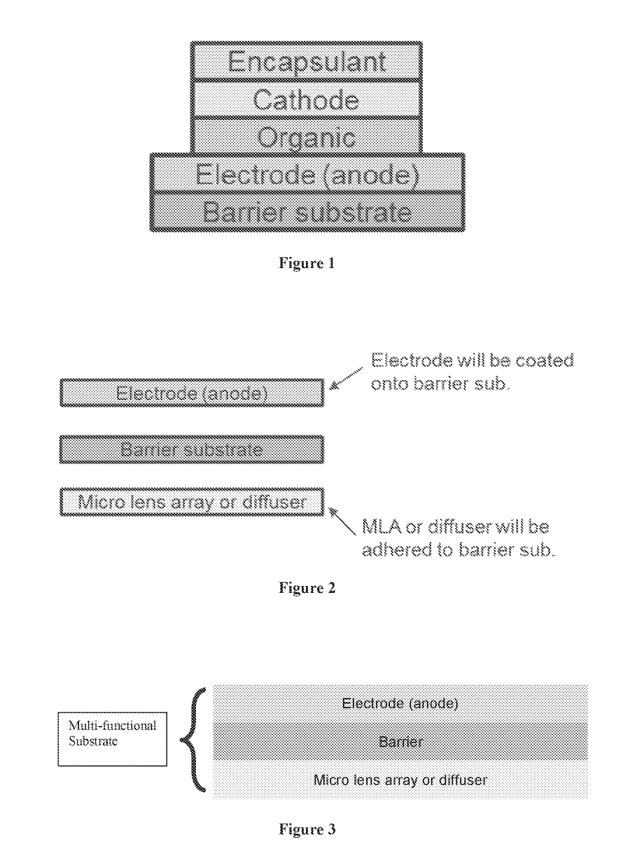

### DETAILED DESCRIPTION OF ILLUSTRATIVE EMBODIMENTS

In some aspects, the disclosure concerns multifunctional flexible substrates suitable for use in an organic light emitting diode element, the flexible substrate comprising a barrier layer; a transparent electrode layer; and a microlens array layer comprising particles; wherein the barrier layer, the electrode layer, and the microlens array layer are formed into a single sheet. The single sheet construction provides an efficiency and economic advantage over constructs of the art that use separate sheets for each layer that then must be laminated into an OLED. The electrode film can be prepared and laminated onto a barrier film or coated on the barrier layer, while other layers can be attached by non-adhesive means. For example, the microlens array layer can be deposited directly onto the barrier or other layer. Some constructs have an electrode layer, a refractive index layer, a barrier layer, a microlens array and phosphor layer where the plurality of layers form a single sheet.

### Substrate

The multifunctional flexible substrate may contain a base substrate that is a plastic material having transparency. Suitable plastic materials include polycarbonate (PC), polyethylene terephthalate (PET), polyethylene naphthalate (PEN), polybutylene terephthalate (PBT) or other polyester, polyether sulfone (PES), and polyether ether ketone (PEEK). Typically, PEN or PET is used for base substrate. PC films may also be useful. Important properties as a base substrate are surface roughness and transparency and chemical resistance. PEN showed good results in terms of those properties. Initial thickness for base substrate may be 100 to 150 um for handling purposes. While a thin film is desired, a film that is too thin can be difficult to control. Regardless of the properties in base substrate, coated materials are important to make a high performance barrier. Therefore, machinery for the process to optimize the density of coated material is also important. Thickness of the coating layer may be 100 to 150 nm.

### Microlens Layer

The microlens layer serves as a light scattering layer having a base material and a plurality of scattering materials dispersed within. The refractive index of the base material and that of the light scattering material are different. Normally, base material's refractive index ranges from 1.4 to 1.6, while scattering particle's refractive index ranges from 1.8 to above 2.0. Therefore, through adding scattering particles into base polymer, total refractive index could be increased. Typically, the light scattering layer is about 5 μm to about 50 μm in thickness.

The scattering materials are composed of air bubbles or particles of a material that are different from the base material. The scattering material may be organic polymer particles or inorganic particles. Inorganic particles include TiO₂, Nb₂O₅, WO₃, Bi₂O₃, La₂O₃, Gd₂O₃, Y₂O₃, ZrO₂, ZnO, BaO, PbO and Sb₂O₃, P₂O₅, SiO₂, B₂O₃, GeO₂ and TeO₂. The amount of added scattering material ranges from about 0.1 wt % to about 90 wt % relative to the amount of base material. It is preferred that the amount of added scattering material ranges from about 0.5 to about 80 wt %, or from about 1 to about 70 wt % or from about 5 to about 60 wt % or from about 10 to about 50 wt %, or from about 20 to about 75 wt %, or any combination of the aforementioned percentages.

The base material may comprise transparent organic polymers. Suitable polymers include polycarbonate (PC), poly(methyl methacrylate) (PMMA) and polyethylene terephthalate (PET).

### Barrier Layer

The barrier layers may comprise one or both of inorganic and organic materials. For example, the barrier layer may comprise inorganic particles in a polymer media. The layer may comprise a metal oxide such as oxides of aluminum, zirconium, zinc, titanium, and silicone (such as Al₂O₃, ZrO₂, ZnO, TiO₂, TiOₓ, SiO₂, and SiOₓ), and a polymer comprising acrylate-polymer, parylene, p-xylene, or ethylene glycol. Polymer layers may be formed by molecular layer deposition (e.g., by molecular layer deposition of ethylene-glycol), plasma polymer (e.g., direct radical polymerization by plasma) or other applications known to those skilled in the art. Typically, the layer has a thickness of from about 0.5 um to about 50 um.

### Electrode Layer

The electrode is transparent and is constructed from materials such as ITO, SnO₂, ZnO, iridium zinc oxide, ZnO—Al₂O₃ (a zinc oxide doped with aluminum), ZnO₄Ga₂O₃ (a zinc oxide doped with gallium), Nb-doped TiO₂, Ta-doped TiO₂, and metals such as Au and Pt. Typically the layer has a thickness of about 50 nm to about 1 μm, 100 nm to about 1 μm.

### Light Extraction Layer

A significant amount of light produced in an OLED device can be lost by trapping at layer interfaces. Inclusion of light extraction layer can serve to reduce this loss in efficiency.

Light extraction layers may be placed at any position that achieves the objective of improving efficiency of the device. Some devices have a light extraction layer between an external layer and the air interface. Certain light extraction layers are positioned between the air interface and the microlens array layer and the air interface or between the microlens array layer and the barrier substrate or between the micro lens array layer and the refractive index matching layer.

Some light extraction layers include topographical features such as micro-grooves, microlenses, or diffractive gratings.

The light extraction layer may be formed from any suitable material. Suitable light extraction layers may comprise an inorganic barrier layer or a high refractive index inorganic or organic layer. In some constructions, polymer films having a high refractive index, such as polyethylene terephthalate, (PET) and polyethylene naphthalate (PEN) films having refractive indexes of about 1.6 and about 1.7 respectively may be used. Some inorganic layers comprise zirconium oxide.

### Phosphor Layer

The phosphor layer may comprise a phosphorescent dopant in a polymer that is transparent when the layer is formed. Different phosphorescent dopants are known in the art and can be selected based on desired color output and other properties. Such dopants include use of YAG:Ce phosphors for yellow and CASN:Eu phosphors for red. YAG is yttrium aluminum garnet (Y₃Al₅O₁₂). YAG:Ce is cerium-doped YAG (YAG:Ce). CASN is CaAlSiN₃ and CASN:Eu is europium-doped CASN.

Silicones such as polydimethylsiloxane (PDMS) or acrylic or urethane based material could be used as binder material.

### Refractive Index Matching Layer

A refractive index matching layer can be inserted between electrode (refractive index=1.6 to 1.8) and organic layer (refractive index=1.7 to 2.0). Therefore, the refractive index value is typically from 1.6 to 2.0. Also, this matching layer may be applied between the barrier and microlens array (extraction) film or between the barrier and electrode layers.

Polyethylenimine (PEI) and polyethylene naphthalate (PEN) may be used for their high refractive index. Through modification of the backbone, the refractive index can be tuned.

In addition, Pixelligent markets nano zirconium oxides which are said to be able to alter the overall refractive index of the polymer system in excess of 1.85. However these systems are rather expensive.

Using micron sized particles produces reflection at the polymer-particle interphase. However if the particle size becomes smaller than the wavelength of the light, it will contribute to the refractive index. Similar to the nano zirconium oxides discussed above, nano-particles like nano TiO₂, ZnO, and others function similarly. PEN may be used as the carrier.

Ultem™ (an amorphous thermoplastic polyetherimide resin marketed by SABIC Innovative Plastics) has one of the highest (inherent) refractive indexes of all polymers—around 1.7 and is only (marginally) outperformed for this property by some more exotic contact lens materials (thiourethanes and alkylene sulfide polymers). See the table below, which includes both PC and Ultem™.

Specification of Optical-Grade Plastics

| | Properties | | | | | |
|---|---|---|---|---|---|---|
| Refractive | Acrylic | Polycarbonate | Polystyrene | Cyclic Olefin | Cyclic Olefin | Ultem ^{™} 1010 |
| Index (RI) | (PMMA) | (PC) | (PS) | Copolymer | Polymer | (PEI) |
| NF (486.1 nm) | 1.497 | 1.599 | 1.604 | 1.540 | 1.537 | 1.689 |
| Nd (589.3 nm) | 1.491 | 1.585 | 1.590 | 1.530 | 1.530 | 1.682 |
| Mc (656.3 nm) | 1.489 | 1.579 | 1.584 | 1.5276 | 1.527 | 1.653 |

In the above table, Nf denotes the index of refraction at 486.1 nm. Nd denotes the index of refraction that has been measured at the wavelength of 589.3 nm. Mc denotes the refractive index at 656.3 nm.

It should also be noted that foams have increased reflectivity because of more air/polymer interfaces. Reflectivity increases with smaller cell size, but this relation is not linear. Reflectivity can also be influenced by certain additives.

### Polymers

Various polymers disclosed herein are available from commercial sources.

### Polycarbonate

The terms “polycarbonate” or “polycarbonates” as used herein include copolycarbonates, homopolycarbonates and (co)polyester carbonates.

The term polycarbonate can be further defined as compositions have repeating structural units of the formula (1):

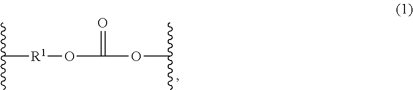

in which at least 60 percent of the total number of R¹ groups are aromatic organic radicals and the balance thereof are aliphatic, alicyclic, or aromatic radicals. In a further aspect, each R¹ is an aromatic organic radical and, more preferably, a radical of the formula (2):

-A1-Y1-A2- (2),

wherein each of A1 and A2 is a monocyclic divalent aryl radical and Y1 is a bridging radical having one or two atoms that separate A1 from A2. In various aspects, one atom separates A1 from A2. For example, radicals of this type include, but are not limited to, radicals such as —O—, —S—, —S(O)—, —S(O₂)—, —C(O)—, methylene, cyclohexyl-methylene, 2-[2.2.1]-bicycloheptylidene, ethylidene, isopropylidene, neopentylidene, cyclohexylidene, cyclopentadecylidene, cyclododecylidene, and adamantylidene. The bridging radical Y1 is preferably a hydrocarbon group or a saturated hydrocarbon group such as methylene, cyclohexylidene, or isopropylidene. Polycarbonate materials include materials disclosed and described in U.S. Pat. No. 7,786,246, which is hereby incorporated by reference in its entirety for the specific purpose of disclosing various polycarbonate compositions and methods for manufacture of the same.

A melt polycarbonate product may be utilized in the instant invention. The melt polycarbonate process is based on continuous reaction of a dihydroxy compound and a carbonate source in a molten stage. The reaction can occur in a series of reactors where the combined effect of catalyst, temperature, vacuum, and agitation allows for monomer reaction and removal of reaction by-products to displace the reaction equilibrium and effect polymer chain growth. A common polycarbonate made in melt polymerization reactions is derived from bisphenol A (BPA) via reaction with diphenyl carbonate (DPC). This reaction can be catalyzed by, for example, tetra methyl ammonium hydroxide (TMAOH) or tetrabutyl phosphonium acetate (TBPA), which can be added in to a monomer mixture prior to being introduced to a first polymerization unit and sodium hydroxide (NaOH), which can be added to the first reactor or upstream of the first reactor and after a monomer mixer.

### Polyetherimides

As disclosed herein, the composition can comprise polyetherimides. Polyetherimides includes polyetherimide copolymers. The polyetherimide can be selected from (i) polyetherimide homopolymers, e.g., polyetherimides, (ii) polyetherimide co-polymers, e.g., polyetherimidesulfones, and (iii) combinations thereof. Polyetherimides are known polymers and are sold by SABIC Innovative Plastics under the ULTEM™, EXTEM™, and SILTEM™ brands.

In an aspect, the polyetherimides can be of formula (3):

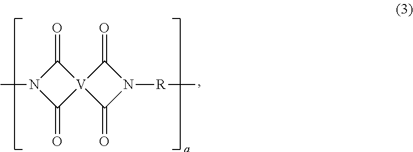

wherein a is more than 1, for example 10 to 1,000 or more, or more specifically 10 to 500. In one example, a can be 10-100, 10-75, 10-50 or 10-25.

The group V in formula (3) is a tetravalent linker containing an ether group (a “polyetherimide” as used herein) or a combination of an ether groups and arylenesulfone groups (a “polyetherimidesulfone”). Such linkers include but are not limited to: (a) substituted or unsubstituted, saturated, unsaturated or aromatic monocyclic and polycyclic groups having 5 to 50 carbon atoms, optionally substituted with ether groups, arylenesulfone groups, or a combination of ether groups and arylenesulfone groups; and (b) substituted or unsubstituted, linear or branched, saturated or unsaturated alkyl groups having 1 to 30 carbon atoms and optionally substituted with ether groups or a combination of ether groups, arylenesulfone groups, and arylenesulfone groups; or combinations comprising at least one of the foregoing. Suitable additional substitutions include, but are not limited to, ethers, amides, esters, and combinations comprising at least one of the foregoing.

The R group in formula (3) includes but is not limited to substituted or unsubstituted divalent organic groups such as: (a) aromatic hydrocarbon groups having 6 to 20 carbon atoms and halogenated derivatives thereof; (b) straight or branched chain alkylene groups having 2 to 20 carbon atoms; (c) cycloalkylene groups having 3 to 20 carbon atoms, or (d) divalent groups of formula (4):

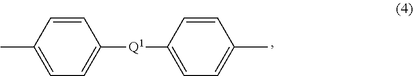

wherein Q1 includes but is not limited to a divalent moiety such as —O—, —S—, —C(O)—, —SO₂—, —SO—, —CyH₂y- (y being an integer from 1 to 5), and halogenated derivatives thereof, including perfluoroalkylene groups.

The disclosure also utilizes the polyimides disclosed in U.S. Pat. No. 8,784,719 which is incorporated herein in its entirety. In addition, the polyetherimide resin can be selected from the group consisting of a polyetherimide, for example as described in U.S. Pat. Nos. 3,875,116; 6,919,422 and 6,355,723, a silicone polyetherimide, for example as described in U.S. Pat. Nos. 4,690,997; 4,808,686, a polyetherimidesulfone resin, as described in U.S. Pat. No. 7,041,773, and combinations thereof, each of these patents are incorporated herein by their entirety.

The polyetherimides can have a weight average molecular weight (Mw) of 5,000 to 100,000 grams per mole (g/mole) as measured by gel permeation chromatography (GPC). In some aspects the Mw can be 10,000 to 80,000. The molecular weights as used herein refer to the absolute weight average molecular weight (Mw).

### Other Polymers

Other polymers discussed herein are available from commercial sources or can be made by methods known to those skilled in the art.

### Formation of Layers Within the Flexible Substrate

In some aspects, the disclosure concerns multifunctional flexible substrates suitable for use in an organic light emitting diode element, the flexible substrate comprising a barrier layer; a transparent electrode layer; and a microlens array layer comprising particles; wherein the barrier layer, the electrode layer, and the microlens array layer are formed into a single sheet in the absence of an adhesive layer.

Certain aspects concern a single layer multifunctional flexible substrate comprising a barrier layer; a transparent electrode layer; at least one microlens array layer comprising particles; at least one refractive index matching layer; and a phosphor layer. In some constructs, the barrier layer, the electrode layer, and the microlens array layer are formed into a single sheet in the absence of an adhesive layer. In some constructs, no adhesive is used in forming the multilayers into a single sheet.

Layers may be formed by use of one or more of ink jet printing, application of a polymer solution or slurry, roll to roll printing, vacuum vapor deposition operations or other techniques known to those skilled in the art. Additionally, aerosol-deposition process can be used for phosphor layer coating. Microlens array film can be made by slot die coating and extrusion methods.

Certain layers of the instant invention may be laminated. The disclosure contemplates all combinations of laminated and non-laminated assembly of each layer into a single sheet.

### Definitions

It is to be understood that the terminology used herein is for the purpose of describing particular aspects only and is not intended to be limiting. As used in the specification and in the claims, the term “comprising” can include the embodiments “consisting of” and “consisting essentially of” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “transparent” means that the level of transmittance for a disclosed composition is greater than 50%. It is preferred that the transmittance be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

The terms “refractive index” or “index of refraction” as used herein refer to a dimensionless number that is a measure of the speed of light in that substance or medium. It is typically expressed as a ratio of the speed of light in vacuum relative to that in the considered substance or medium. This can be written mathematically as:

n=speed of light in a vacuum/speed of light in medium.

The term “adhesive” as used herein refers to a sticky, gluey or tacky substance capable of adhering two films together. It is preferred that the adhesive be transparent. In the adhesive, desiccant material can be added for improving WVTR property. And UV or thermal energy may be necessary for curing adhesive layer.

“UV” stands for ultraviolet.

The abbreviation “nm” stands for nanometer(s).

The abbreviation “um” stands for micrometer(s).

As used herein the terms “weight percent,” “wt. %,” and “wt. %” of a component, which can be used interchangeably, unless specifically stated to the contrary, are based on the total weight of the formulation or composition in which the component is included. For example if a particular element or component in a composition or article is said to have 8% by weight, it is understood that this percentage is relative to a total compositional percentage of 100% by weight.

As used herein, the terms “weight average molecular weight” or “Mw” can be used interchangeably, and are defined by the formula:

$${M}_{w} = \frac{\sum {N}_{i} {M}_{i}^{2}}{\sum {N}_{i} {M}_{i}} ,$$

where Mᵢ is the molecular weight of a chain and Nᵢ is the number of chains of that molecular weight. Compared to Mₙ, M_{w} takes into account the molecular weight of a given chain in determining contributions to the molecular weight average. Thus, the greater the molecular weight of a given chain, the more the chain contributes to the M_{w}. M_{w} can be determined for polymers, e.g. polycarbonate polymers, by methods well known to a person having ordinary skill in the art using molecular weight standards, e.g. polycarbonate standards or polystyrene standards, preferably certified or traceable molecular weight standards.

Unless otherwise stated to the contrary herein, all test standards are the most recent standard in effect at the time of filing this application.

### Aspects

The present disclosure comprises at least the following aspects.

Aspect 1. A multifunctional flexible substrate suitable for use in an organic light emitting diode element, said flexible substrate comprising a barrier layer; a transparent electrode layer; and a microlens array layer comprising particles; wherein the barrier layer, the electrode layer, and the microlens array layer are formed into a single sheet in the absence of an adhesive layer.

Aspect 2. The multifunctional flexible substrate of Aspect 1, wherein the barrier layer is disposed between and contacting the electrode and microlens array layers.

Aspect 3. The multifunctional flexible substrate of Aspect 1 or Aspect 2, wherein the barrier layer and the electrode layer are adjacent and the microlens array layer is disposed on one or both of the barrier layer and the electrode layer.

Aspect 4. The multifunctional flexible substrate of any one of Aspects 1-3, additionally comprising a refractive index matching layer.

Aspect 5. The multifunctional flexible substrate of Aspect 4, wherein the barrier layer is disposed between and contacting the electrode and microlens array layers; and the refractive index matching layer contacts: (i) the microlens array layer; or (ii) each of the microlens array layer and the electrode layer.

Aspect 6. The multifunctional flexible substrate of Aspect 4, wherein the barrier layer is disposed between and contacting the electrode and microlens array layers; and the flexible substrate comprises two refractive index layers and two microlens array layers such that a first refractive index matching layer contacts a first microlens array layer and a second refractive index matching layer contacts each of a second microlens array layer and the electrode layer.

Aspect 7. The multifunctional flexible substrate of any one of Aspects 1-6, additionally comprising a light extraction layer.

Aspect 8. The multifunctional flexible substrate of any one of Aspects 1-7, wherein the microlens array layer comprises a polymer having a refractive index that is equal to or higher than that of the barrier layer.

Aspect 9. The multifunctional flexible substrate of any one of Aspects 1-8, wherein the particles comprise one or more of zircon, silica, alumina, TiO₂ and ZnO.

Aspect 10. The multifunctional flexible substrate of any one of Aspects 1-9, wherein the particle have a diameter of about 0.1 μm to about 20 μm.

Aspect 11. The multifunctional flexible substrate of any one of Aspects 1-10, wherein the barrier layer comprises a metal oxide dispersed in a polymer.

Aspect 12. The multifunctional flexible substrate of any one of Aspects 1-11, wherein the electrode layer comprises indium tin oxide, zinc oxide, Ag or Pt.

Aspect 13. The multifunctional flexible substrate of any one of Aspects 1-12, wherein the microlens layer comprises polycarbonate.

Aspect 14. The multifunctional flexible substrate of any one of Aspects 1-13, wherein the refractive index layer comprises polycarbonate, polyethylene terephthalate or polyethylene naphthalate.

Aspect 15. The multifunctional flexible substrate of any one of Aspects 1-14, additionally comprising a phosphor layer.

Aspect 16. The multifunctional flexible substrate of any one of Aspects 1-15, wherein said barrier layer comprises an oxide of aluminum, zirconium, zinc, titanium or silicon and a polymer comprising at least one of acrylate, p-xylene and ethylene-glycol

Aspect 17. A multifunctional flexible substrate suitable for use in an organic light emitting diode element, said flexible substrate comprising a barrier layer; a transparent electrode layer; at least one microlens array layer comprising particles; at least one refractive index matching layer; and a phosphor layer.

Aspect 18. The multifunctional flexible substrate of Aspect 17, wherein at least one refractive index matching polymer layer contacts a microlens array layer.

Aspect 19. The multifunctional flexible substrate of Aspect 17 or Aspect 18, wherein the electrode layer contacts the barrier layer.

Aspect 20. The multifunctional flexible substrate of Aspect 17, having layers in order (i) a first microlens array layer, (ii) refractive index matching layer, (iii) electrode layer, (iv) barrier layer, and (v) a second microlens array layer.

Aspect 21. The multifunctional flexible substrate of Aspect 17, having layers in order: (i) a refractive index matching layer, (ii) a first microlens array layer, (iii) an electrode layer, (iv) a barrier layer, and (v) a second microlens array layer.

Aspect 22. The multifunctional flexible substrate of Aspect 17, having layers in order: (i) a first microlens array layer, (ii) a first refractive index matching layer, (iii) an electrode layer, (iv) a barrier layer, (v) a second microlens array layer, and (vi) a second refractive index matching layer.

Aspect 23. The multifunctional flexible substrate of any one of Aspects 1-16, having layers in order: (i) electrode layer, (ii) barrier layer, and (iii) microlens array layer.

Aspect 24. A method of forming a multifunctional flexible substrate comprising forming a barrier layer, an electrode layer, a microlens layer and a barrier layer onto a plastic substrate by use of one or more of ink jet printing, vapor phase deposition, application of a polymer solution or slurry, and roll to roll printing, said forming done substantially in the absence of an adhesive.

Aspect 25. The method of Aspect 24, further comprising adding one or more of a phosphor layer and a refractive index matching layer.

Aspect 26. A multifunctional flexible substrate suitable for use in an organic light emitting diode element, said flexible substrate comprising:

a barrier layer;

a transparent electrode layer;

at least one microlens array layer comprising particles;

at least one refractive index matching polymer layer; and

a phosphor layer.

Aspect 27. The multifunctional flexible substrate of Aspect 26, wherein at least one refractive index matching polymer layer contacts a microlens array layer.

Aspect 28. The multifunctional flexible substrate of Aspect 26 or Aspect 27, wherein the electrode layer contacts the barrier layer.

Aspect 29. The multifunctional flexible substrate of any one of Aspects 26-28, wherein the refractive index layer comprises polycarbonate, polyethylene terephthalate, or polyethylene naphthalate.

Aspect 30. The multifunctional flexible substrate of any one of Aspects 26-29 wherein said barrier layer comprises an oxide of aluminum, zirconium, zinc, titanium, or silicon, and a polymer comprising at least one of acrylate, p-xylene, and ethylene-glycol.

Aspect 31. A multifunctional substrate comprising a barrier layer and a light extraction layer.

Aspect 32. A multifunctional substrate comprising a barrier layer and an electrode layer.

### EXAMPLES

The disclosure is illustrated by the following non-limiting examples.

Various examples of multi-functional substrates are constructed as depicted in FIGS. 3-5.

A multi-functional substrate combined with a barrier layer, a transparent electrode, and a light extraction film as one sheet solution in the absence of an adhesive is shown in FIG. 3.

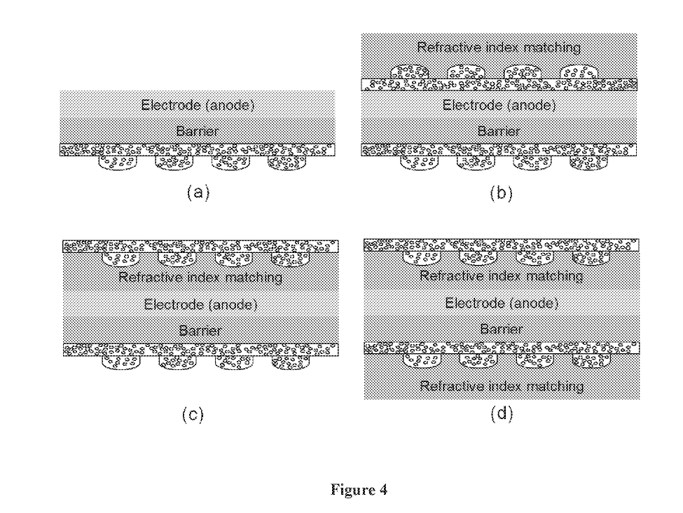

Structure of a microlens array (MLA) with particles can be constructed on one side or both sides of the barrier/electrode construct as depicted in FIG. 4. A refractive index matching polymer can be coated as shown in FIGS. 4(b), (c), (d).

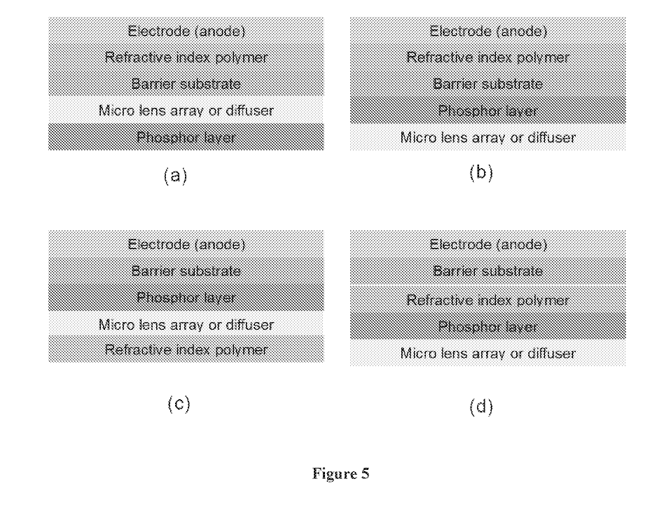

Additional layers can be added for improving extraction efficiency. A phosphor layer and/or high or low refractive index polymer can be placed on the substrate. FIG. 5 shows representative examples of stacked structures of integrated substrates.

1. A multifunctional flexible substrate suitable for use in an organic light emitting diode element, said flexible substrate comprising:
a barrier layer;
a transparent electrode layer; and
a microlens array layer comprising particles;
wherein the barrier layer, the electrode layer, and the microlens array layer are formed into a single sheet in the absence of an adhesive layer.

2. The multifunctional flexible substrate of claim 1, wherein the barrier layer is disposed between and contacting the electrode and microlens array layers.

3. The multifunctional flexible substrate of claim 1, wherein the barrier layer and the electrode layer are adjacent and the microlens array layer is disposed on one or both of the barrier layer and the electrode layer.

4. The multifunctional flexible substrate of claim 1, additionally comprising a refractive index matching layer.

5. The multifunctional flexible substrate of claim 4, wherein
the barrier layer is disposed between and contacting the electrode and microlens array layers; and
the refractive index matching layer contacts:
(i) the microlens array layer; or
(ii) each of the microlens array layer and the electrode layer.

6. The multifunctional flexible substrate of claim 4, wherein
the barrier layer is disposed between and contacting the electrode and microlens array layers; and
the flexible substrate comprises two refractive index layers and two microlens array layers such that a first refractive index matching layer contacts a first microlens array layer and a second refractive index matching layer contacts each of a second microlens array layer and the electrode layer.

7. The multifunctional flexible substrate of claim 1, additionally comprising a light extraction layer.

8. The multifunctional flexible substrate of claim 1, wherein the microlens array layer comprises a polymer having a refractive index that is equal to or higher than that of the barrier layer.

9. The multifunctional flexible substrate of claim 1, wherein the particles comprise one or more of zircon, silica, alumina, TiO₂, and ZnO.

10. The multifunctional flexible substrate of claim 1, wherein the particles have a diameter of about 0.1 μm to about 20 μm.

11. The multifunctional flexible substrate of claim 1, wherein the barrier layer comprises a metal oxide dispersed in a polymer.

12. The multifunctional flexible substrate of claim 1, wherein the electrode layer comprises indium tin oxide, zinc oxide, Ag, or Pt.

13. The multifunctional flexible substrate of claim 1, wherein the microlens layer comprises polycarbonate.

14. The multifunctional flexible substrate of claim 1, additionally comprising a phosphor layer.

15. A method of forming a multifunctional flexible substrate comprising forming a barrier layer, an electrode layer, a microlens layer, and a barrier layer onto a plastic substrate by use of one or more of ink jet printing, vapor phase deposition, application of a polymer solution or slurry, and roll to roll printing, said forming done substantially in the absence of an adhesive.

16. A multifunctional flexible substrate suitable for use in an organic light emitting diode element, said flexible substrate comprising:
a barrier layer;
a transparent electrode layer;
at least one microlens array layer comprising particles;
at least one refractive index matching polymer layer; and
a phosphor layer.

17. The multifunctional flexible substrate of claim 16, wherein the at least one refractive index matching polymer layer contacts the at least one microlens array layer.

18. The multifunctional flexible substrate of claim 16 claim 16, wherein the electrode layer contacts the barrier layer.

19. The multifunctional flexible substrate of claim 16, wherein the refractive index layer comprises polycarbonate, polyethylene terephthalate, or polyethylene naphthalate.

20. The multifunctional flexible substrate of claim 16 wherein said barrier layer comprises an oxide of aluminum, zirconium, zinc, titanium, or silicon, and a polymer comprising at least one of acrylate, p-xylene, and ethylene-glycol.
